(19) United States
(12) Patent Application Publication
(10) Pub. No.: US 2025/0107126 A1
(43) Pub. Date: Mar. 27, 2025

(54) SEMICONDUCTOR DEVICE AND MANUFACTURING METHOD THEREOF

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Tomohiro TANIGUCHI, Nomi Ishikawa (JP)

(21) Appl. No.: 18/599,965

(22) Filed: Mar. 8, 2024

(30) Foreign Application Priority Data
Sep. 22, 2023 (JP) 2023-158093

(51) Int. Cl. H01L 29/739; C23C 18/54; H01L 23/00; H01L 29/66

(52) U.S. Cl. CPC H10D 12/481; C23C 18/54; H01L 24/06; H01L 24/45; H01L 24/48; H10D 12/032; H01L 2224/0603; H01L 2224/45124; H01L 2224/48724; H01L 2924/13055

(57) ABSTRACT

A semiconductor device according to an embodiment includes a semiconductor substrate; a first electrode provided on the semiconductor substrate, and the first electrode containing aluminum; a second electrode provided on the semiconductor substrate, the second electrode being provided separately from the first electrode, and the second electrode containing aluminum; a third electrode provided on the first electrode, and the third electrode containing aluminum oxide.

### CROSS-REFERENCE TO RELATED APPLICATION

This application is based upon and claims the benefit of priority from Japanese Patent Application No. 2023-158093, filed on Sep. 22, 2023, the entire contents of which are incorporated herein by reference.

### FIELD

Embodiments described herein relate generally to a semiconductor device and a method of manufacturing the semiconductor device.

### BACKGROUND

An IGBT (Insulated Gate Bipolar Transistor) or the semiconductor device having a semiconductor chip such as a MOSFET (Metal Oxide Semiconductor Field Effect Transistor) is used for power converting or the like. For example, when the above-described semiconductor device is the IGBT, the emitter electrode provided on an upper surface of the semiconductor chip is connected to, for example, a connector or a bonding wire provided above the IGBT.

### BRIEF DESCRIPTION OF THE DRAWINGS

FIG. 1 is a schematic cross-sectional view of the semiconductor device according to a first embodiment;

FIG. 2 is a schematic top view illustrating a semiconductor substrate, a first insulating film, a first electrode, and a second electrode of the first embodiment;

FIGS. 3A-B are schematic cross-sectional views of a main part of the semiconductor device of the first embodiment;

FIG. 4 is a schematic cross-sectional view illustrating a process of manufacturing the semiconductor device according to the first embodiment;

FIG. 5 is a schematic cross-sectional view illustrating the process of manufacturing the semiconductor device according to the first embodiment;

FIGS. 6A-B are schematic cross-sectional views illustrating the process of manufacturing the semiconductor device according to the first embodiment;

FIGS. 7A-B are schematic cross-sectional views illustrating the process of manufacturing the semiconductor device according to the first embodiment;

FIG. 8 is a flow chart illustrating the process of manufacturing the semiconductor device according to the first embodiment;

FIG. 9 is a schematic cross-sectional view of a main part of the semiconductor device as a first comparative example of the first embodiment;

FIG. 10 is a schematic cross-sectional view of a main part of the semiconductor device as a second comparative example of the first embodiment;

FIG. 11 is a schematic cross-sectional view of the semiconductor device according to a second embodiment;

FIG. 12 is a schematic cross-sectional view illustrating a part of the manufacturing process of the semiconductor device according to the second embodiment;

FIG. 13 is a schematic cross-sectional view of the semiconductor device according to a third embodiment;

FIG. 14 is a schematic cross-sectional view illustrating a process of manufacturing the semiconductor device according to the third embodiment;

FIG. 15 is a schematic cross-sectional view illustrating the process of manufacturing the semiconductor device according to the third embodiment;

FIG. 16 is a schematic cross-sectional view illustrating the process of manufacturing the semiconductor device according to the third embodiment; and

FIG. 17 is a schematic cross-sectional view illustrating a main part of the manufacturing process of the semiconductor device according to the fourth embodiment.

### DETAILED DESCRIPTION

A semiconductor device according to an embodiment includes a semiconductor substrate; a first electrode provided on the semiconductor substrate, and the first electrode containing aluminum; a second electrode provided on the semiconductor substrate, the second electrode being provided separately from the first electrode, and the second electrode containing aluminum; a third electrode provided on the first electrode, and the third electrode containing aluminum oxide.

Hereinafter, embodiments of the present disclosure will be described with reference to the drawings. Note that in the following description, the same members and the like are denoted by the same reference numerals, and description of members and the like once described is appropriately omitted.

In this specification, in order to illustrate the positional relationship of parts and the like, the upward direction of the drawings may be referred to as “upper”, and the downward direction of the drawings may be referred to as “lower”. Here, the terms “up” and “down” do not necessarily indicate a relationship with the direction of gravity.

(First embodiment) A semiconductor device according to the present embodiment includes a semiconductor substrate; a first electrode provided on the semiconductor substrate, and the first electrode containing aluminum; a second electrode provided on the semiconductor substrate, the second electrode being provided separately from the first electrode, and the second electrode containing aluminum; a third electrode provided on the first electrode, and the third electrode containing aluminum oxide; a sixth electrode provided on the second electrode, and the sixth electrode containing nickel; and a seventh electrode provided on the sixth electrode, and the seventh electrode containing gold.

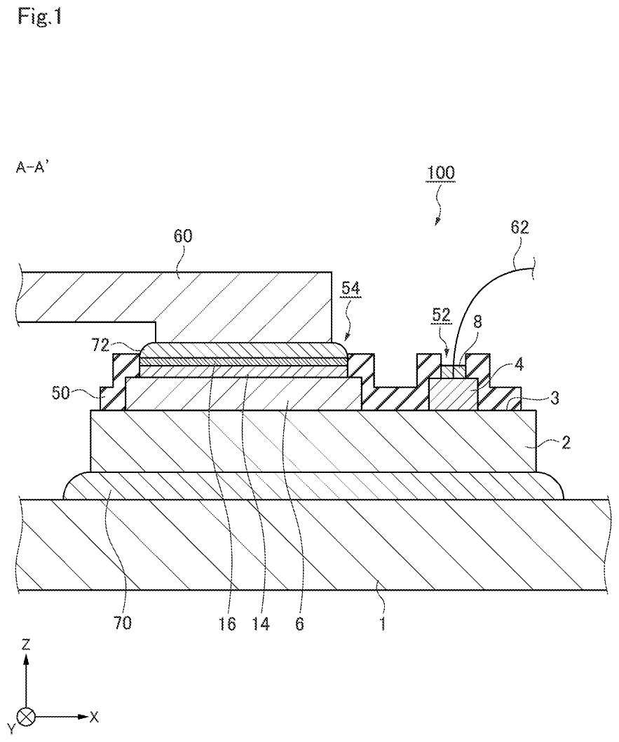

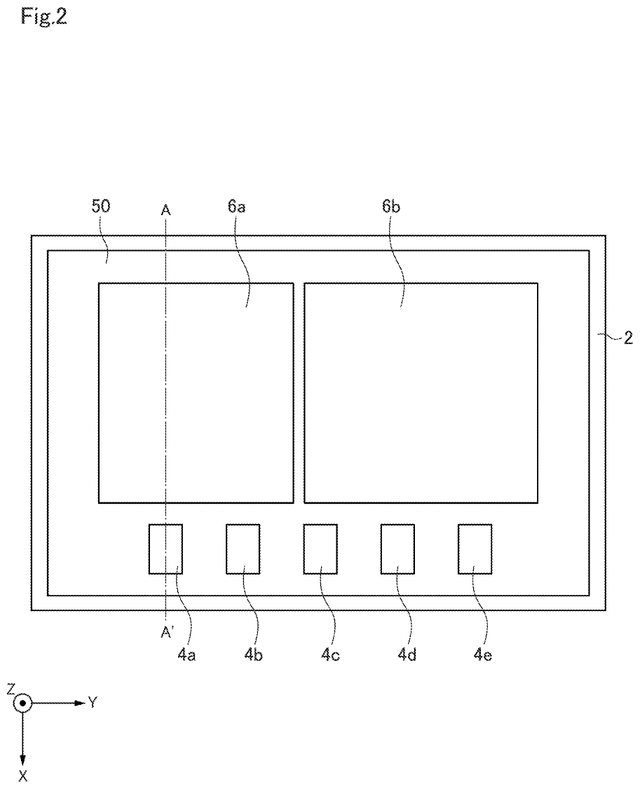

FIG. 1 is the schematic cross-sectional view of the semiconductor device 100 according to the present embodiment. FIG. 2 is the schematic top view showing the semiconductor substrate 2, the first insulating film 50, the first electrode 4, and the second electrode 6 of the semiconductor device of the present embodiment.

FIG. 1 is the schematic cross-sectional view in an A-A′ cross-section of FIG. 2.

In FIG. 2, a part of the elements illustrated in FIG. 1 is omitted.

A die pad 1 is a member containing a conductive material such as Cu on which the semiconductor substrate 2 is disposed. The die pad 1 is used to connect the semiconductor substrate 2 to an external circuit (not shown).

The semiconductor substrate 2 is provided on the die pad 1. The semiconductor substrate 2 has a substrate surface (the upper surface) 3. The semiconductor substrate 2 of the present embodiment is, for example, the substrate such as a Si (silicon) substrate, a SiC (silicon carbide) substrate, or a GaAs (gallium arsenide) substrate, or a GaN (gallium nitride) semiconductor layer provided on the Si substrate, with a vertical IGBT or a vertical MOSFET.

Hereinafter, the semiconductor substrate 2 will be described as the substrate having the IGBT.

Here, an X direction, a Y direction vertically crossing the X direction, and a Z direction vertically crossing the X direction and the Y direction are defined. The substrate surface 3 of the semiconductor substrate 2 is disposed parallel to XY surface.

The first electrode 4 is provided on the substrate surface 3 of the semiconductor substrate 2. The first electrode 4 is, for example, an electrode electrically connected to the IGBT. The first electrode 4 is, for example, an electrode for performing Kelvin connection to the IGBT. The first electrode 4 contains, for example, Al (aluminum). The first electrode 4 is, for example, an electrode containing Al as a main component. The first electrode 4 is, for example, an Al electrode. The first electrode 4 may contain an element other than Al.

The second electrode 6 is provided on the substrate surface 3 of the semiconductor substrate 2 and is provided separately from the first electrode 4. The second electrode 6 is, for example, electrically connected to the emitter of IGBT. The second electrode 6 contains, for example, Al. The second electrode 6 is, for example, an electrode containing Al as a main component. The second electrode 6 is, for example, an Al electrode. The second electrode 6 may contain an element other than Al.

For example, as shown in FIG. 2, a plurality of the first electrodes 4 may be provided, such as the first electrodes 4a, 4b, 4c, 4d and 4e. Further, for example, as shown in FIG. 2, a plurality of the second electrodes 6 may be provided, such as the second electrodes 6a and 6b.

Under the semiconductor substrate 2, an electrode (not shown) connected to the collector of the IGBT is provided.

The second bonding material 70 is provided between the semiconductor substrate 2 and the die pad 1. The second bonding material 70 electrically connects, for example, the die pad 1 to the collector of IGBT. The second bonding material 70 is, for example, solder. However, the second bonding material 70 is not limited to the solder.

The third electrode 8 is provided on the first electrode 4. The third electrode 8 contains aluminum oxide. The third electrode 8 is, for example, in direct contact with the first electrode 4. The third electrode 8 is electrically connected to the first electrode 4.

For example, a first bonding wire 62 breaks through the third electrode 8 and is connected to the first electrode 4 by the operation during the bonding. Thus, the first bonding wire 62 is electrically connected to the first electrode 4. The first bonding wire 62 contains, for example, aluminum (Al). The first bonding wire 62 is, for example, an aluminum (Al) wire.

The sixth electrode 14 is provided on the second electrode 6. The sixth electrode 14 contains Ni.

The seventh electrode 16 is provided on the sixth electrode 14. The seventh electrode 16 contains gold (Au). The seventh electrode 16 is used, for example, to prevent oxidation of the sixth electrode 14. The first bonding material 72 is used to join the seventh electrode 16 and the connector 60. Here, the first bonding material 72 is, for example, solder.

Note that a layer containing palladium (Pd) (not shown) may be provided between the sixth electrode 14 and the seventh electrode 16.

The connector 60 is electrically connected to the sixth electrode 14 and the seventh electrode 16. The connector 60 includes, for example, a conductive material such as copper (Cu). Note that the connector 60 may be plated with, for example, a material containing Tin (Sn).

Note that the connector 60 is a rigid connector that cannot be easily bent, and differs from the first bonding wire 62.

The first insulating film 50 is provided on the semiconductor substrate 2. The first insulating film 50 includes a first opening 52 and a second opening 54. Inside the first opening 52, the first electrode 4 and the third electrode 8 are provided. Inside the second opening 54, the second electrode 6, the sixth electrode 14, and the seventh electrode 16 are provided. The first insulating film 50 contains, for example, a resin such as a polyimide resin, a benzocyclobutene resin, or an epoxy resin, or silicon nitride. The first insulating film 50 is preferably resistant to a chemical solution used in an electroless nickel-gold plating process described later.

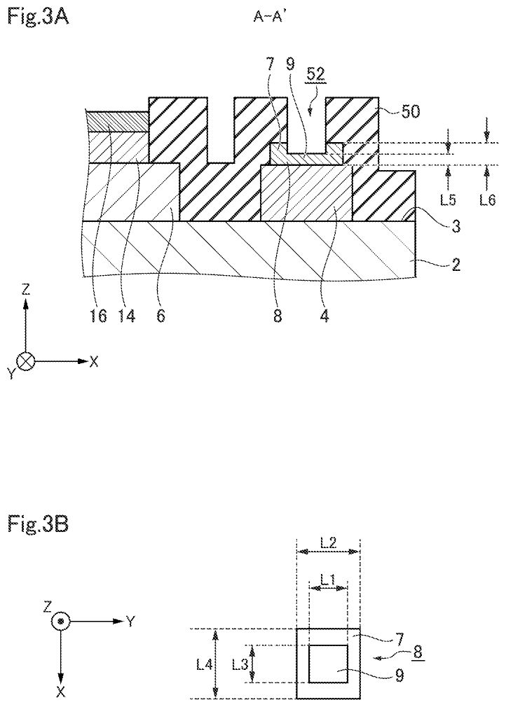

FIGS. 3A-B are the schematic views of the main part of the semiconductor device 100 of the present embodiment. FIG. 3A is the schematic cross-sectional view of the third electrode 8 and its vicinity of the semiconductor device 100 of the present embodiment. FIG. 3B is the schematic top view of the third electrode 8 of the present embodiment. In FIGS. 3A-B, a part of the elements shown in FIG. 1 is omitted.

The third electrode 8 includes an end 7 in a plane parallel to the substrate plane 3 and in a plane parallel to XY plane. The concavity 9 is formed by being surrounded by the end 7. The length of the concavity 9 in the X-direction is L3. The length of the third electrode 8 in the X-direction is L4. L4 is longer than L3. The length of the concavity 9 in the Y-direction is L1. The length of the third electrode 8 in the Y-direction is L2. The end 7 is provided around the concavity 9 in a plane parallel to XY plane. L2 is longer than L1.

The first insulating film 50 is provided on the end 7 so as to surround the concavity 9 in a plane parallel to XY plane. The film thickness L6 of the end 7 in the Z-direction is thicker than the film thickness L5 of the concavity 9 in the Z-direction.

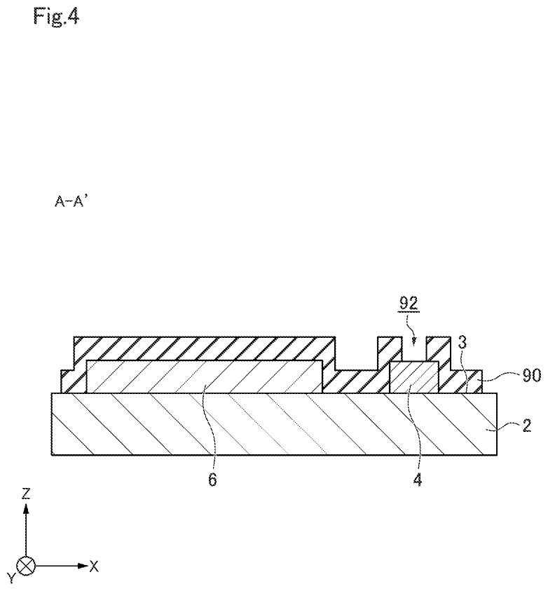

FIGS. 4 to 7 A-B are schematic cross-sectional views illustrating the process of manufacturing the semiconductor device 100 according to the present embodiment.

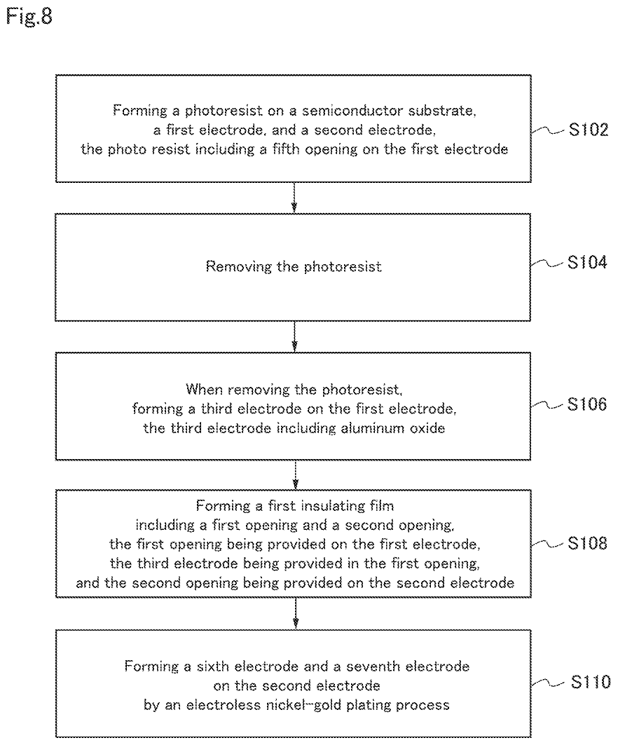

FIG. 8 is a flow chart illustrating the process of manufacturing the semiconductor device 100 according to the present embodiment.

On the substrate surface 3 of the semiconductor substrate 2 having IGBT, the first electrode 4 containing aluminum and the second electrode 6 containing aluminum and provided separately from the first electrode 4 are provided. On the semiconductor substrate 2, the first electrode 4 and the second electrode 6, a photoresist 90 including the fifth opening 92 on the first electrode 4 is formed (FIG. 4, S102 of FIG. 8).

Next, for example, an ashing treatment is performed to remove the photoresist 90. In the ashing treatment, for example, the surface of the photoresist 90 is irradiated with high-energy oxygen plasma to couple the carbon included in the photoresist 90 with the oxygen plasma. In this way, the photoresist 90 is decomposed as CO2.

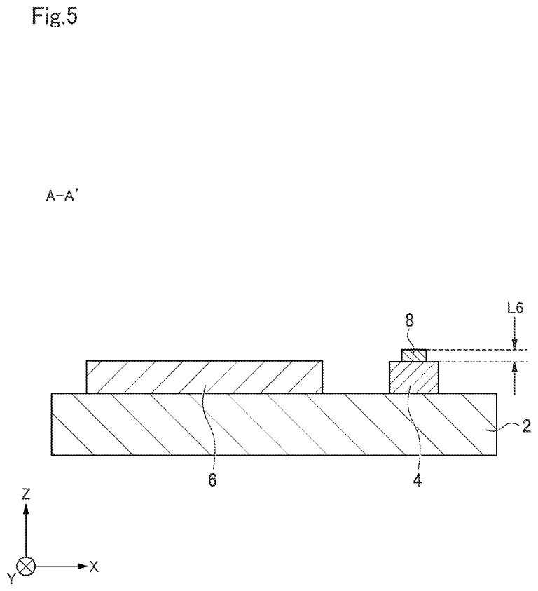

When the oxygen plasma is irradiated to remove the photoresist, in the fifth opening 92, the surface of the first electrode 4 is oxidized to form the third electrode 8 containing aluminum oxide on the first electrode 4 (FIGS. 5, S104 and S106 of FIG. 8). As a result, the third electrode 8 having the film thickness thicker than 10 nm can be formed. Note that the film thickness L6 of the third electrode 8 formed by the manufacturing method of the semiconductor device of the present embodiment is, for example, thicker than 8 nm and 15 nm or less. Further, the film thickness of the third electrode 8 formed by the manufacturing method of the semiconductor device of the present embodiment is, more preferably, thicker than 10 nm and 15 nm or less. Further, more preferably, the film thickness of the third electrode 8 formed by the manufacturing method of the semiconductor device of the present embodiment is, thicker than 12 nm and 15 nm or less. In addition to the ashing treatment, the third electrode 8 containing aluminum oxide can be formed by removing photoresist 90 using, for example, an organic solvent.

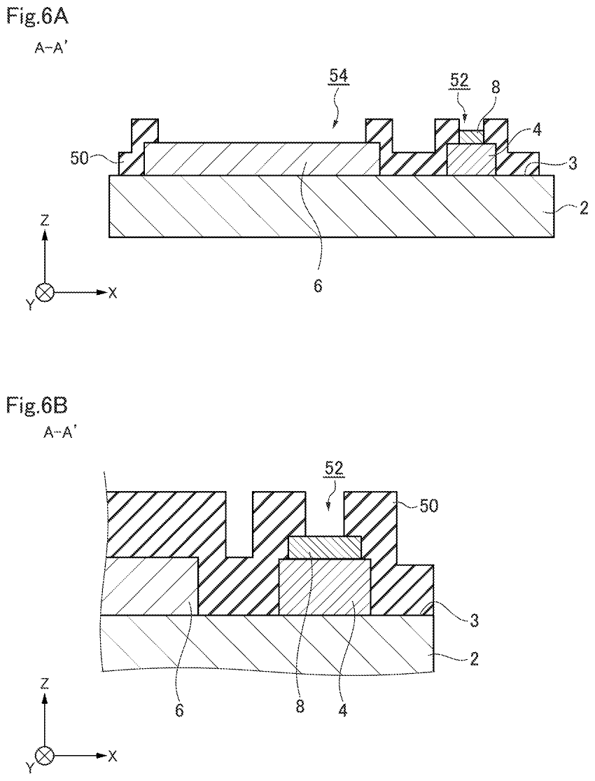

Next, the first insulating film 50 is formed on the semiconductor substrate 2, the first electrode 4, and the second electrode 6. The first insulating film 50 contains a resin such as polyimide, silicon nitride, or the like. Here, the first insulating film 50 includes the first opening 52 and the second opening 54. The first opening 52 is provided on the first electrode 4. The third electrode 8 is provided inside the first opening 52. The second opening 54 is provided on the second electrode 6. Here, the first insulating film 50 is formed so that the area on the third electrode 8 where the end 7 is to be formed is covered with the first insulating film 50 (FIG. 6B). This is because, when the first electrode 4 is exposed, a nickel-containing electrode and a gold-containing electrode are formed on the first electrode 4. (FIGS. 6A-B and S108 of FIG. 8).

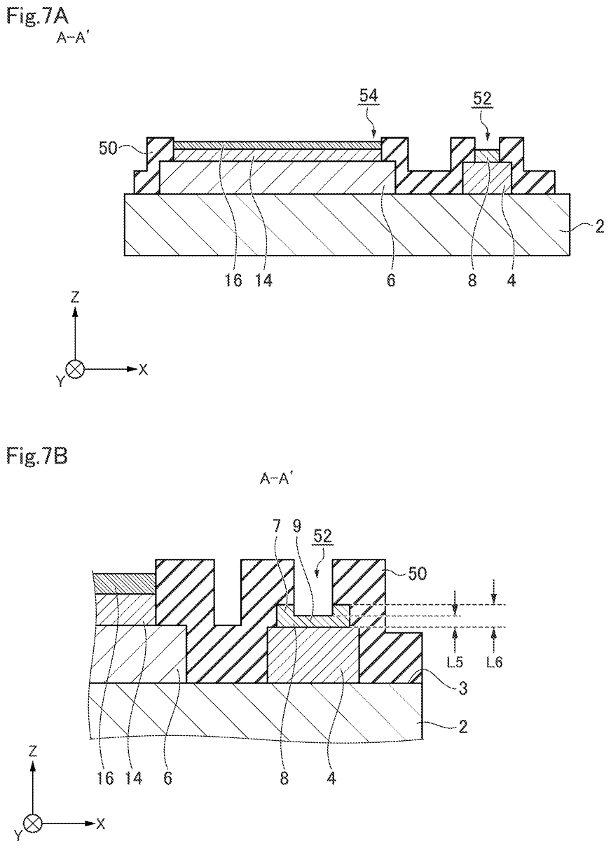

Next, the sixth electrode 14 and the seventh electrode 16 are formed in the second opening 54 on the second electrode 6 by, for example, an electroless nickel-gold plating process. In the electroless nickel-gold plating process, first, strongly acidic chemical treatment and strong alkaline chemical treatment are performed. Strong alkaline chemical treatment removes the aluminum-containing native oxide film, which is not shown, even if it is formed on the second electrode 6. Here, the film thickness of such native oxide film is generally 10 nm or less. On the other hand, if the film thickness of the third electrode 8 is sufficiently thick, the third electrode 8 remains on the first electrode 4 even if the strong alkaline chemical treatment is performed. Here, for example, the third electrode 8 can be left on the first electrode 4 by controlling the duration of the treatment of the strongly alkaline chemical solution and the temperature of the strongly alkaline chemical solution. This forms a nickel-containing sixth electrode 14 on the second electrode 6 and a gold-containing seventh electrode 16 on the sixth electrode 14 (FIGS. 7A-B and S110 of FIG. 8).

Incidentally, by the strong alkaline chemical treatment described above, the concavity 9 surrounded by the end 7 is formed in the third electrode 8. The film thickness of the concavity 9 is L5 and is thinner than L6. On the other hand, since the end 7 of the third electrode 8 is covered with the first insulating film 50, the film thickness of the end 7 is maintained at L6. On the third electrode 8, an electrode containing nickel and an electrode containing gold are not formed.

Next, the semiconductor substrate 2 is connected to the die pad 1 using the second bonding material 70, the first bonding wire 62 is connected to the first electrode 4, the connector 60 is electrically connected to the sixth electrode 14 and the seventh electrode 16 using the first bonding material 72, thereby obtaining the semiconductor device 100 of the present embodiment.

Next, functions and effects of the semiconductor device and the method of manufacturing the semiconductor device according to the present embodiment will be described.

When the semiconductor substrate having the IGBT or the like is electrically connected to an external circuit by using the connector, a method using, for example, solder, is used as the bonding material. Here, there is a problem that the solder does not wet and spread on the electrode containing aluminum as a main component. Thus, for example, an electrode containing nickel and gold is formed on an electrode containing aluminum by the electroless nickel-gold plating method. In the electroless nickel-gold plating method, a nickel plating film can be selectively formed on the electrode containing aluminum as a main component. Further, it is possible to selectively form a metal on the nickel plating film.

On the other hand, when the semiconductor substrate having a IGBT or the like is electrically connected to the external circuit using the bonding wire, an aluminum wire is often used. When the bonding is performed using the aluminum wire, wedge bonding is mainly performed by bonding between aluminum and aluminum. Therefore, it is required that a material containing aluminum is exposed on the outermost surface of the electrode containing aluminum as a main component.

The bonding using the connector can improve the heat dissipation property from the semiconductor substrate. On the other hand, in the case of the bonding using the bonding wire, the mounting area of the semiconductor package using the semiconductor device can be reduced. Therefore, it is conceivable to bond the connector to the electrode that is preferable to ensure the heat dissipation characteristics, and to bond the bonding wire to the electrode that is not important to ensure the heat dissipation characteristics.

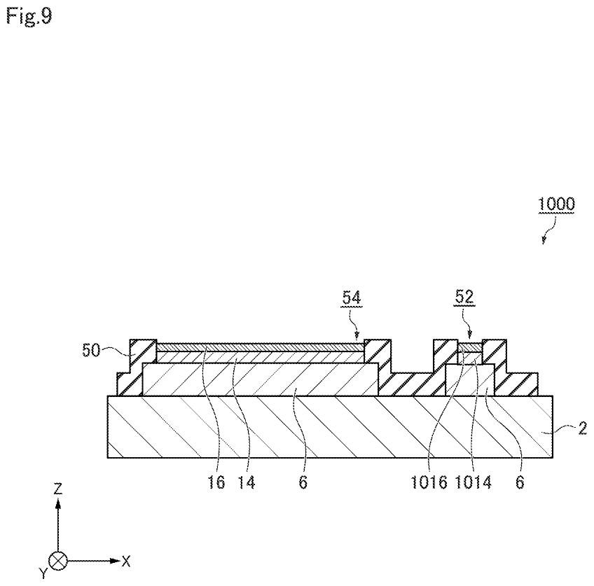

FIG. 9 shows the schematic cross-sectional view of the main part of the semiconductor device 1000 as the first comparative example of the present embodiment. In the semiconductor device 1000, the sixth electrode 14 containing Ni is provided on the second electrode 6. The seventh electrode 16 containing gold (Au) is provided on the sixth electrode 14.

A ninth electrode 1014 containing Ni is provided on the first electrode 4. A tenth electrode 1016 containing Au is provided on the ninth electrode 1014.

In the manufacture of the semiconductor device 1000, an electroless nickel-gold plating method is simply applied. In this way, electrodes containing nickel and gold are formed on both of the first electrode 4 and the second electrode 6.

Simply applying an electroless nickel-gold plating method, such as the semiconductor device 1000, results in the formation of the electrodes containing nickel and the electrodes containing gold on all of the electrodes. Therefore, the bonding wire cannot be connected.

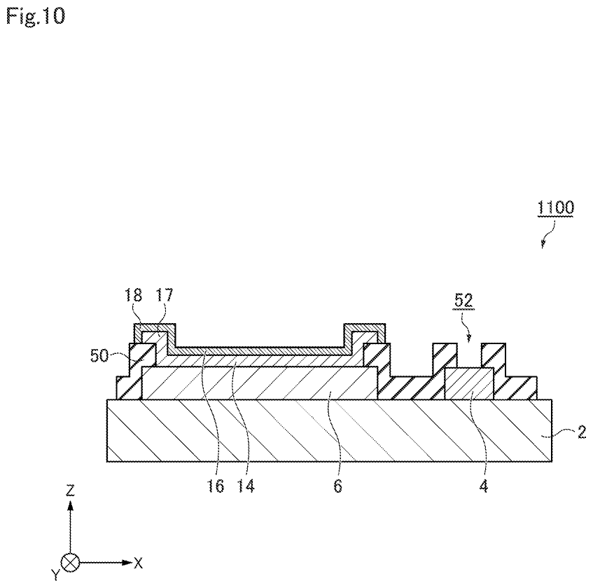

FIG. 10 shows the schematic cross-sectional view of the main part of the semiconductor device 1100 as the second comparative example of the present embodiment. In the semiconductor device 1100, the sixth electrode 14 and the seventh electrode 16 are formed on the second electrode 6 by a sputtering device using a metal mask (not shown). However, if the metal mask and the first insulating film 50 are misaligned, an electrode 17 that is a part of the sixth electrode 14 and an electrode 18 that is a part of the seventh electrode 16 may be formed on the first insulating film 50. In this case, the stress caused by the electrode 17 and the electrode 18 causes a defect in the connection to the connector 60, which degrades the reliability of the semiconductor device 100.

Therefore, the semiconductor device of the present embodiment includes a semiconductor substrate; a first electrode provided on the semiconductor substrate, and the first electrode containing aluminum; a second electrode provided on the semiconductor substrate, the second electrode being provided separately from the first electrode, and the second electrode containing aluminum; a third electrode provided on the first electrode, and the third electrode containing aluminum oxide; a sixth electrode provided on the second electrode, and the sixth electrode containing nickel; and a seventh electrode provided on the sixth electrode, and the seventh electrode containing gold.

According to the semiconductor device of the present embodiment, both the third electrode 8 containing aluminum oxide, and the sixth electrode 14 and the seventh electrode 16, can be provided on one semiconductor substrate 2. Therefore, the connector 60 can be bonded to the sixth electrode 14 and the seventh electrode 16 via the first bonding material 72. Further, the first bonding wire 62 may be connected to the third electrode 8. Therefore, a highly reliable semiconductor device can be obtained.

By the manufacturing method mentioned above, the first insulating film 50 is provided on the end 7 of the third electrode 8, and the end 7 is provided on the third electrode 8 in a direction parallel to the substrate plane 3 of the semiconductor substrate 2. Further, the film thickness L6 of the end 7 of the third electrode 8 is thicker than the film thickness L5 of the concavity 9 of the third electrode 8.

According to the semiconductor device of the present embodiment, a highly reliable semiconductor device can be provided. Further, according to the manufacturing method of the semiconductor device of the present embodiment, it is possible to provide the manufacturing method of the semiconductor device capable of manufacturing highly reliable semiconductor device.

(Second Embodiment) The semiconductor device of the present embodiment includes a semiconductor substrate; a first electrode provided on the semiconductor substrate, and the first electrode containing aluminum; a second electrode provided on the semiconductor substrate, the second electrode being provided separately from the first electrode, and the second electrode containing aluminum; a third electrode provided on the first electrode, and the third electrode containing aluminum oxide.

Here, a description of contents overlapping with those of the first embodiment will be omitted.

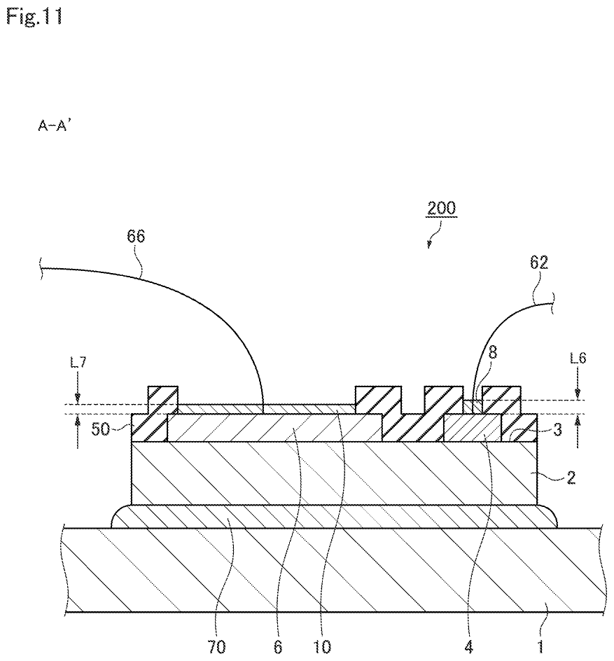

FIG. 11 is the schematic cross-sectional view of the semiconductor device 200 according to the present embodiment. A fourth electrode 10 containing aluminum oxide is provided on the second electrode 6. The film thickness L7 of the fourth electrode 10 is ½ or less of the film thickness L6 of the end 7 of the third electrode 8.

The second bonding wire 66 breaks through the fourth electrode 10 and is connected to the second electrode 6 by, for example, the operation during the bonding. Accordingly, the second bonding wire 66 is electrically connected to the second electrode 6. The second bonding wire 66 contains, for example, aluminum (Al). The second bonding wire 66 is, for example, an aluminum (Al) wire.

In the same manner as shown in FIG. 3A and FIG. 3B, in a plane parallel to the substrate plane 3 and parallel to XY plane, the third electrode 8 is provided with a concavity 9 surrounded by the end 7. The length of the concavity 9 in the X-direction is L3. The length of the third electrode 8 in the X-direction is L4. The length of the concavity 9 in the Y-direction is L1. The length of the third electrode 8 in the Y-direction is L2. In a plane parallel to XY plane, the end 7 is provided around the concavity 9. The first insulating film 50 is provided on the end 7 so as to surround the concavity 9 in a plane parallel to XY plane. The film thickness L6 of the end 7 in the Z-direction is thicker than the film thickness L5 of the concavity 9 in the Z-direction.

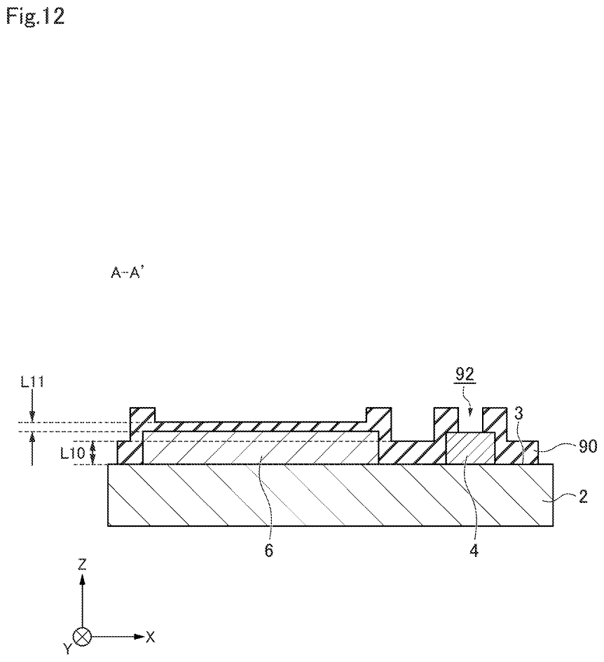

FIG. 12 is the schematic cross-sectional view showing a part of the manufacturing process of the semiconductor device 200 of the present embodiment.

For example, as shown in FIG. 12, the photoresist 90 is formed where the film thickness L11 of the photoresist 90 on the second electrode 6 is thinner than the film thickness L10 of the photoresist 90 on the substrate surface 3 of the semiconductor substrate 2 between the first electrode 4 and the second electrode 6. As a result, the photoresist 90 on the second electrode 6 is removed by the ashing process faster than the photoresist 90 on the other parts. Thus, the fourth electrode 10 containing aluminum oxide and having the film thickness thinner than that of the third electrode 8 can be formed on the second electrode 6. By controlling the film thickness of the photoresist 90 on the second electrode 6, the relationship between the film thickness of the third electrode 8 and the film thickness of the fourth electrode 10 can be controlled.

According to the semiconductor device of the present embodiment, a highly reliable semiconductor device can be provided. Further, according to the manufacturing method of the semiconductor device of the present embodiment, it is possible to provide the manufacturing method of the semiconductor device capable of manufacturing highly reliable semiconductor device.

(Third embodiment) The semiconductor device of the present embodiment differs from the semiconductor device of the first and second embodiments in that the semiconductor device further includes a second insulating film having a third opening and a fourth opening, the third opening being provided on the first opening, the fourth opening being provided on the second opening, and the second insulating film containing a resin, wherein the first insulating film contains silicon oxide or silicon nitride. Here, a description of contents overlapping with those of the first and second embodiments will be omitted.

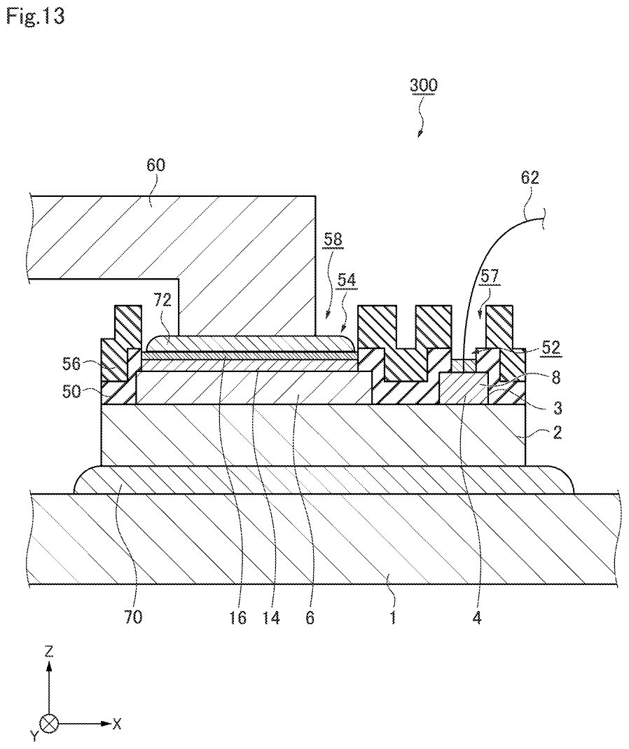

FIG. 13 is the schematic cross-sectional view of the semiconductor device 300 according to the present embodiment.

The first insulating film 50 of the semiconductor device 300 of the present embodiment contains, for example, silicon oxide or silicon nitride.

The second insulating film 56 is provided on the first insulating film 50. The second insulating film 56 includes the third opening 57 and the fourth opening 58. The third opening 57 is provided on the first opening 52. The fourth opening 58 is provided on the second opening 54. The second insulating film 56 contains a resin such as a polyimide resin, a benzocyclobutene resin, or an epoxy resin.

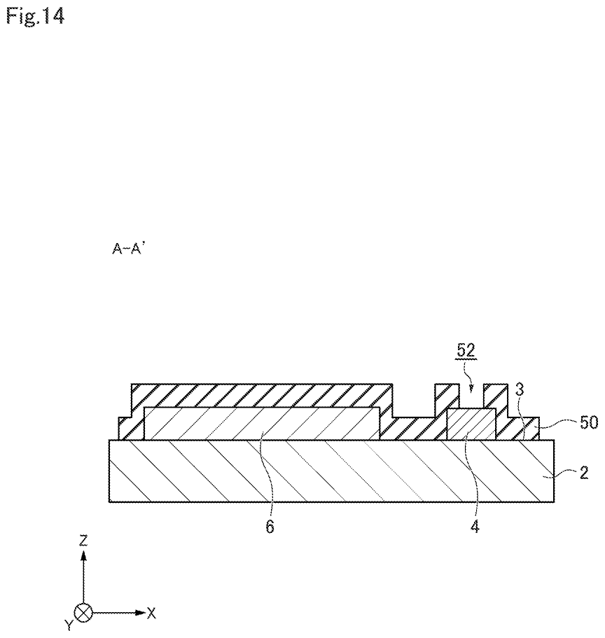

FIGS. 14 to 16 are the schematic cross-sectional views illustrating a process of manufacturing the semiconductor device 300 according to the present embodiment.

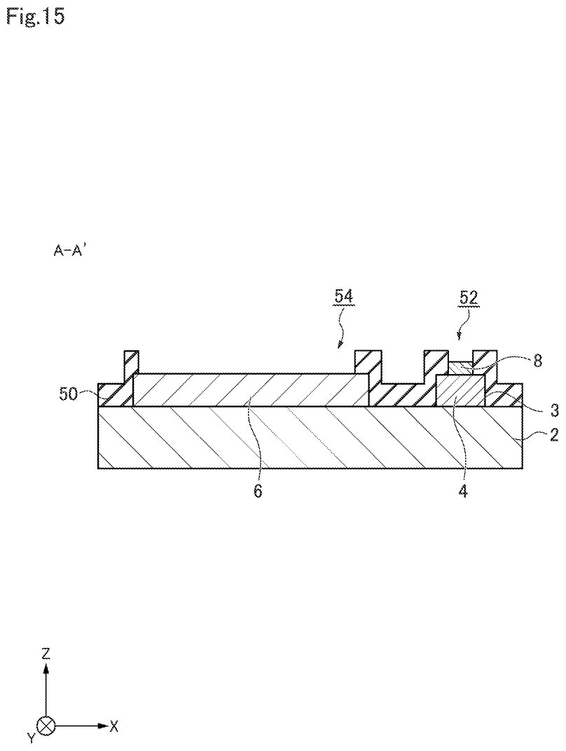

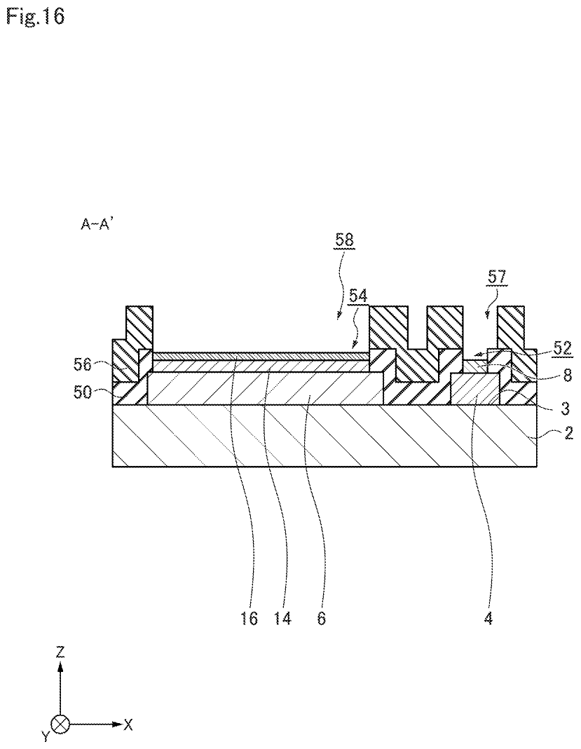

The first insulating film 50 having the first opening 52 on the first electrode and containing silicon oxide or silicon nitride is formed (FIG. 14). Next, when the oxygen plasma is irradiated by, for example, the ashing process, the third electrode 8 containing aluminum oxide is formed on the first electrode 4 in the first opening 52. Next, the second opening 54 of the first insulating film 50 is formed on the second electrode 6 (FIG. 15). Next, the sixth electrode 14 and the seventh electrode 16 are formed on the second electrode 6 by the electroless nickel-gold plating. Next, on the first insulating film 50, the second insulating film 56 having the third opening provided on the first opening and the fourth opening provided on the second opening is formed (FIG. 16).

As in the present embodiment, the first insulating film 50 containing silicon oxide or silicon nitride may be used as a mask material for forming the third electrode 8 containing aluminum oxide.

According to the semiconductor device of the present embodiment, a highly reliable semiconductor device can be provided. Further, according to the manufacturing method of the semiconductor device of the present embodiment, it is possible to provide the manufacturing method of the semiconductor device capable of manufacturing highly reliable semiconductor device.

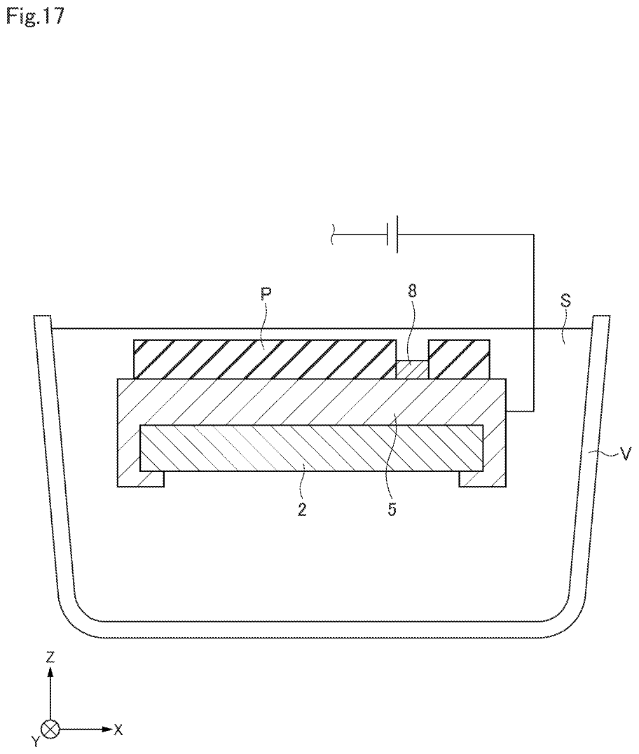

(Fourth embodiment) FIG. 17 is the schematic cross-sectional view showing the main part of a step of the manufacturing method of the semiconductor device of the present embodiment. Here, a description of contents overlapping with those of the first, second and third embodiments will be omitted.

A protective material P having the opening P1 is formed on the aluminum base material 5 formed on the semiconductor substrate 2. Next, the semiconductor device being manufactured is immersed in the chromic acid aqueous solution S in the container V. The protective material P is resistant to the chromic acid aqueous solution S. As the protective material P, for example, a photoresist, a metallic thin film containing gold or platinum, a silicon oxide or a silicon nitride is used. Then, the third electrode 8 is formed by anodizing using the chromic acid aqueous solution S. When anodic treatment is used, the third electrode 8 having the film thickness of at most 100 nm or the like can be formed.

According to the semiconductor device of the present embodiment, a highly reliable semiconductor device can be provided. Further, according to the manufacturing method of the semiconductor device of the present embodiment, it is possible to provide the manufacturing method of the semiconductor device capable of manufacturing highly reliable semiconductor device.

While certain embodiments and examples have been described, these embodiments and examples have been presented by way of example only, and are not intended to limit the scope of the inventions. Indeed, the novel embodiments described herein may be embodied in a wide variety of other forms; furthermore, various omissions, substitutions and changes in the form of the embodiments described herein may be made without departing from the spirit of the inventions. These embodiments and variations thereof fall within the scope and spirit of the invention, and fall within the scope of the invention described in the claims and equivalents thereof.

The above-described embodiments can be summarized in the following technical solutions.

(Technical proposal 1). A semiconductor device comprising:
a semiconductor substrate;
a first electrode provided on the semiconductor substrate, and the first electrode containing aluminum;
a second electrode provided on the semiconductor substrate, the second electrode being provided separately from the first electrode, and the second electrode containing aluminum; and
a third electrode provided on the first electrode, and the third electrode containing aluminum oxide.

(Technical proposal 2). The semiconductor device according to technical proposal 1, further comprising:

a fourth electrode provided on the second electrode, the fourth electrode containing aluminum oxide, and a film thickness of the fourth electrode is ½ or less of a film thickness of the third electrode.

(Technical proposal 3). The semiconductor device according to technical proposal 2, further comprising:
a first insulating film provided on the semiconductor substrate, the first insulating film including a first opening and a second opening,
wherein the first electrode and the third electrode are provided in the first opening,
and wherein the second electrode and the fourth electrode are provided in the second opening,
and wherein the third electrode includes a concavity surrounded by an end of the third electrode in a plane parallel to an upper surface of the semiconductor substrate,
and wherein the first insulating film is provided on the end, and the first insulating film is provided to surround the concavity in the plane parallel to the upper surface of the semiconductor substrate.

(Technical proposal 4). The semiconductor device according to technical proposal 1, further comprising:
a sixth electrode provided on the second electrode, and the sixth electrode containing nickel; and
a seventh electrode provided on the sixth electrode, and the seventh electrode containing gold.

(Technical proposal 5). The semiconductor device according to technical proposal 4, further comprising:
a first insulating film provided on the semiconductor substrate, the first insulating film including a first opening and a second opening,
wherein the first electrode and the third electrode are provided in the first opening,
and wherein the second electrode, the sixth electrode and the seventh electrode are provided in the second opening,
and wherein the third electrode has a concavity surrounded by an end of the third electrode in a plane parallel to an upper surface of the semiconductor substrate,
and wherein the first insulating film is provided on the end, and the first insulating film is provided to surround the concavity in the plane parallel to the upper surface of the semiconductor substrate.

(Technical proposal 6). The semiconductor device according to technical proposal 4,
wherein the film thickness of the third electrode is thicker than 8 nm.

(Technical proposal 7). The semiconductor device according to technical proposal 6,
wherein the film thickness of the third electrode is 15 nm or less.

(Technical proposal 8). The semiconductor device according to technical proposal 3,
wherein a length of the first opening on the third electrode in a direction parallel to the upper surface of semiconductor substrate is shorter than the length of the third electrode in the direction parallel to the upper surface of the semiconductor substrate.

(Technical proposal 9). The semiconductor device according to technical proposal 5,
wherein a length of the first opening on the third electrode in a direction parallel to the upper surface of semiconductor substrate is shorter than the length of the third electrode in the direction parallel to the upper surface of the semiconductor substrate.

(Technical proposal 10). The semiconductor device according to technical proposal 3, further comprising:
a second insulating film having a third opening and a fourth opening, the third opening being provided on the first opening, the fourth opening being provided on the second opening, and the second insulating film containing a resin,
wherein the first insulating film contains silicon oxide or silicon nitride.

(Technical proposal 11). The semiconductor device according to technical proposal 5,
a second insulating film having a third opening and a fourth opening, the third opening being provided on the first opening, the fourth opening being provided on the second opening, and the second insulating film containing a resin,
wherein the first insulating film contains silicon oxide or silicon nitride.

(Technical proposal 12). The semiconductor device according to technical proposal 1, further comprising:

a first bonding wire electrically connected to the first electrode, and the first bonding wire containing aluminum; and
a second bonding wire electrically connected to the second electrode, and
the second bonding wire containing aluminum.

(Technical proposal 13). The semiconductor device according to technical proposal 4, further comprising:
a first bonding wire electrically connected to the first electrode, and the first bonding wire containing aluminum; and
a connector electrically connected to the seventh electrode.

(Technical proposal 14). A method of manufacturing a semiconductor device, comprising:
forming a photoresist including a fifth opening on a first electrode, the first electrode being provided on a semiconductor substrate, a second electrode being provided on the semiconductor substrate, the second electrode being provided separately from the first electrode, the first electrode containing aluminum, and the second electrode containing aluminum;
removing the photoresist;
forming a third electrode on the first electrode in the fifth opening when removing the photoresist, the third electrode containing aluminum oxide;
forming a first insulating film on the semiconductor substrate, the first electrode, the second electrode, and the third electrode, the first insulating film including
   a first opening provided on the third electrode, and
   a second opening provided on the second electrode;
forming a sixth electrode and a seventh electrode by an electroless nickel-gold plating process, the sixth electrode being provided on the second electrode,
the sixth electrode being provided in the second opening, the sixth electrode containing nickel, the seventh electrode being provided on the sixth electrode in the second opening, and the seventh electrode containing gold; and forming a concavity on the third electrode by the electroless nickel-gold plating process, the concavity being surrounded by an end on the third electrode,
and an area on the end being covered with the first insulating film.

(Technical proposal 15). The method of manufacturing the semiconductor device according to technical proposal 14, further comprising:
forming a second insulating film on the first insulating film, the second insulating film including a third opening provided on the first opening and a fourth opening provided on the second opening, the second insulating film containing a resin,
wherein the first insulating film including silicon oxide or silicon nitride.

(Technical proposal 16). The method of manufacturing the semiconductor device according to technical proposal 14, further comprising:
connecting a first bonding wire to the first electrode electrically; and
connecting a connector to the seventh electrode electrically.

(Technical proposal 17). A method of manufacturing a semiconductor device, comprising:
forming a photoresist including a fifth opening on a first electrode, the first electrode being provided on a semiconductor substrate, a second electrode being provided on the semiconductor substrate, the second electrode being provided separately from the first electrode, the first electrode containing aluminum, the second electrode containing aluminum, and a film thickness of the photoresist on the second electrode being thinner than the film thickness of the photoresist on an upper surface of the semiconductor substrate between the first electrode and the second electrode;
removing the photoresist;
when removing the photoresist, forming a third electrode on the first electrode in the fifth opening, and the third electrode containing aluminum oxide;
when removing the photoresist, forming a fourth electrode on the second electrode, the fourth electrode containing aluminum oxide, and a film thickness of the fourth electrode being ½ or less of a film thickness of the third electrode.

(Technical proposal 18). The method of manufacturing the semiconductor device according to technical proposal 17, further comprising:
forming a first insulating film on the semiconductor substrate, the first electrode, the second electrode, the third electrode and the fourth electrode, the first insulating film including
   a first opening provided on the third electrode, and
   a second opening provided on the fourth electrode.

(Technical proposal 19). The method of manufacturing the semiconductor device according to technical proposal 18, further comprising:
connecting a first bonding wire to the first electrode electrically; and
connecting a second bonding wire to the second electrode electrically.

While certain embodiments have been described, these embodiments have been presented by way of example only, and are not intended to limit the scope of the inventions. Indeed, the semiconductor device and the manufacturing method of the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor substrate;
a first electrode provided on the semiconductor substrate, and the first electrode containing aluminum;
a second electrode provided on the semiconductor substrate, the second electrode being provided separately from the first electrode, and the second electrode containing aluminum; and
a third electrode provided on the first electrode, and the third electrode containing aluminum oxide.

2. The semiconductor device according to claim 1, further comprising:
a fourth electrode provided on the second electrode, the fourth electrode containing aluminum oxide, and a film thickness of the fourth electrode is ½ or less of a film thickness of the third electrode.

3. The semiconductor device according to claim 2, further comprising:
a first insulating film provided on the semiconductor substrate, the first insulating film including a first opening and a second opening,
wherein the first electrode and the third electrode are provided in the first opening,
and wherein the second electrode and the fourth electrode are provided in the second opening,
and wherein the third electrode includes a concavity surrounded by an end of the third electrode in a plane parallel to an upper surface of the semiconductor substrate,
and wherein the first insulating film is provided on the end, and the first insulating film is provided to surround the concavity in the plane parallel to the upper surface of the semiconductor substrate.

4. The semiconductor device according to claim 1, further comprising:
a sixth electrode provided on the second electrode, and the sixth electrode containing nickel; and
a seventh electrode provided on the sixth electrode, and the seventh electrode containing gold.

5. The semiconductor device according to claim 4, further comprising:
a first insulating film provided on the semiconductor substrate, the first insulating film including a first opening and a second opening,
wherein the first electrode and the third electrode are provided in the first opening,
and wherein the second electrode, the sixth electrode and the seventh electrode are provided in the second opening,
and wherein the third electrode has a concavity surrounded by an end of the third electrode in a plane parallel to an upper surface of the semiconductor substrate,
and wherein the first insulating film is provided on the end, and the first insulating film is provided to surround the concavity in the plane parallel to the upper surface of the semiconductor substrate.

6. The semiconductor device according to claim 4,
wherein the film thickness of the third electrode is thicker than 8 nm.

7. The semiconductor device according to claim 6,
wherein the film thickness of the third electrode is 15 nm or less.

8. The semiconductor device according to claim 3,
wherein a length of the first opening on the third electrode in a direction parallel to the upper surface of semiconductor substrate is shorter than the length of the third electrode in the direction parallel to the upper surface of the semiconductor substrate.

9. The semiconductor device according to claim 5,
wherein a length of the first opening on the third electrode in a direction parallel to the upper surface of semiconductor substrate is shorter than the length of the third electrode in the direction parallel to the upper surface of the semiconductor substrate.

10. The semiconductor device according to claim 3, further comprising:
a second insulating film having a third opening and a fourth opening, the third opening being provided on the first opening, the fourth opening being provided on the second opening, and the second insulating film containing a resin,
wherein the first insulating film contains silicon oxide or silicon nitride.

11. The semiconductor device according to claim 5,
a second insulating film having a third opening and a fourth opening, the third opening being provided on the first opening, the fourth opening being provided on the second opening, and the second insulating film containing a resin,
wherein the first insulating film contains silicon oxide or silicon nitride.

12. The semiconductor device according to claim 1, further comprising:
a first bonding wire electrically connected to the first electrode, and the first bonding wire containing aluminum; and
a second bonding wire electrically connected to the second electrode, and the second bonding wire containing aluminum.

13. The semiconductor device according to claim 4, further comprising:
a first bonding wire electrically connected to the first electrode, and the first bonding wire containing aluminum; and
a connector electrically connected to the seventh electrode.

14. A method of manufacturing a semiconductor device, comprising:
forming a photoresist including a fifth opening on a first electrode, the first electrode being provided on a semiconductor substrate, a second electrode being provided on the semiconductor substrate, the second electrode being provided separately from the first electrode, the first electrode containing aluminum, and the second electrode containing aluminum;
removing the photoresist;
forming a third electrode on the first electrode in the fifth opening when removing the photoresist, the third electrode containing aluminum oxide;
forming a first insulating film on the semiconductor substrate, the first electrode, the second electrode, and the third electrode, the first insulating film including
a first opening provided on the third electrode, and
a second opening provided on the second electrode;
forming a sixth electrode and a seventh electrode by an electroless nickel-gold plating process, the sixth electrode being provided on the second electrode, the sixth electrode being provided in the second opening, the sixth electrode containing nickel, the seventh electrode being provided on the sixth electrode in the second opening, and the seventh electrode containing gold; and
forming a concavity on the third electrode by the electroless nickel-gold plating process, the concavity being surrounded by an end on the third electrode, and an area on the end being covered with the first insulating film.

15. The method of manufacturing the semiconductor device according to claim 14, further comprising:
forming a second insulating film on the first insulating film, the second insulating film including a third opening provided on the first opening and a fourth opening provided on the second opening, the second insulating film containing a resin,
wherein the first insulating film including silicon oxide or silicon nitride.

16. The method of manufacturing the semiconductor device according to claim 14, further comprising:
connecting a first bonding wire to the first electrode electrically; and
connecting a connector to the seventh electrode electrically.

17. A method of manufacturing a semiconductor device, comprising:
forming a photoresist including a fifth opening on a first electrode, the first electrode being provided on a semiconductor substrate, a second electrode being provided on the semiconductor substrate, the second electrode being provided separately from the first electrode, the first electrode containing aluminum, the second electrode containing aluminum, and a film thickness of the photoresist on the second electrode being thinner than the film thickness of the photoresist on an upper surface of the semiconductor substrate between the first electrode and the second electrode;
removing the photoresist;
when removing the photoresist, forming a third electrode on the first electrode in the fifth opening, and the third electrode containing aluminum oxide;
when removing the photoresist, forming a fourth electrode on the second electrode, the fourth electrode containing aluminum oxide, and a film thickness of the fourth electrode being ½ or less of a film thickness of the third electrode.

18. The method of manufacturing the semiconductor device according to claim 17, further comprising:
forming a first insulating film on the semiconductor substrate, the first electrode, the second electrode, the third electrode and the fourth electrode, the first insulating film including
a first opening provided on the third electrode, and
a second opening provided on the fourth electrode.

19. The method of manufacturing the semiconductor device according to claim 18, further comprising:
connecting a first bonding wire to the first electrode electrically; and
connecting a second bonding wire to the second electrode electrically.
